(19) United States
(12) Patent Application Publication
(10) Pub. No.: US 2016/0053055 A1
(43) Pub. Date: Feb. 25, 2016

(54) SOLUBLE THERMOPLASTIC POLYIMIDE COMPOSITION, METHOD OF MAKING THE COMPOSITION, POLYIMIDE METAL LAMINATE HAVING CONNECTING LAYER MADE FROM THE COMPOSITION, AND METHOD OF MAKING THE LAMINATE

(71) Applicant: TAIFLEX SCIENTIFIC CO., LTD., KAOHSIUNG (TW)

(72) Inventors: Tzu-Ching Hung, Kaohsiung (TW); Ching-Hung Huang, Kaohsiung (TW); Kuang-Ting Hsueh, Kaohsiung (TW)

(21) Appl. No.: 14/510,213

(22) Filed: Oct. 9, 2014

(30) Foreign Application Priority Data
Aug. 21, 2014 (TW) 103128756

(51) Int. Cl. C08G 73/10; B32B 37/06; B32B 37/10; H05K 1/05

(52) U.S. Cl. CPC C08G 73/1067; H05K 1/056; B32B 37/06; B32B 37/10

(57) ABSTRACT

A method of making a soluble thermoplastic polyimide composition, which comprises the steps of: polymerizing a first diamine, a second diamine different from the first diamine, and a dianhydride in a polar aprotic solvent to obtain a polyamine acid, wherein the first diamine contains a carboxyl group; and imidizing the polyamine acid to obtain the composition, wherein the composition contains the carboxyl group. By controlling the content of the dianhydride within a range from 85 mol. % to 99 mol. % based on the total content of the first diamine and the second diamine, the soluble thermoplastic polyimide composition made from the method can be laminated with a commercial polyimide film and a metal foil via simple steps of coating, drying, and pressing, to form a polyimide metal laminate. Therefore, by utilizing the soluble thermoplastic polyimide composition made from the method, making a polyimide metal laminate is simple and economical.

### BACKGROUND OF THE INVENTION

1. Field of the Invention

The present invention relates to a thermoplastic polyimide composition and a method of making the composition; especially relates to a soluble thermoplastic polyimide composition and a method of making the composition. Also, the present invention relates to a polyimide metal laminate having at least one connecting layer made from the composition and a method of making the laminate. 2. Description of the Prior Art(s)

Flexible printed circuit boards (FPCB), being lightweight, thin, and small, are applied to advanced 3C products, such as intelligence mobile phones.

The conventional glue-free laminate for FPCB is classified into glue-free single-sided copper foil laminate and glue-free double-sided copper foil laminate. In the fabrication of the glue-free single-sided copper foil laminate or glue-free double-sided copper foil laminate, a polyamide acid is coated on a copper foil to form a polyamide acid layer on the copper foil; the polyamide acid layer is dried to form a dried polyamide acid layer on the copper foil; then the dried polyamide acid layer is imidized into a polyimide film on the copper foil by a roll-to-roll processing equipment to obtain the glue-free single-sided copper foil laminate or glue-free double-sided copper foil laminate.

However, to fabricate the glue-free single-sided copper foil laminate or glue-free double-sided copper foil laminate by the roll-to-roll processing equipment, the coating, drying and imidizing of the polyamide acid have to be segmentally proceeded. Therefore, fabrication of the glue-free single-sided copper foil laminate and glue-free double-sided copper foil laminate is complicated and uneconomical.

To overcome the shortcomings, the present invention provides a soluble thermoplastic polyimide composition and a method of making the composition to mitigate or obviate the aforementioned problems.

### SUMMARY OF THE INVENTION

The main objective of the present invention is to provide a soluble thermoplastic polyimide composition and a method of making the composition, wherein the composition is beneficial to simplify the fabrication of a polyimide metal laminate.

The method of making the composition in accordance with the present invention comprises the steps of:

polymerizing a first diamine, a second diamine different from the first diamine, and a dianhydride in a polar aprotic solvent to obtain a polyamine acid, wherein the first diamine contains a carboxyl group and a content of the dianhydride ranges from 85 molar percent (mol. %) to 99 mol. % based on the total content of the first diamine and the second diamine; and

imidizing the polyamine acid to obtain the composition, wherein the composition contains the carboxyl group.

In accordance with the method of making the composition of the present invention, the step of imidizing the polyamine acid to obtain the composition comprises the steps of:

imidizing the polyamine acid to obtain a soluble thermoplastic polyimide; and

mixing the soluble thermoplastic polyimide and a curing agent containing at least two functional groups to obtain the composition, wherein the composition comprises the soluble thermoplastic polyimide and the curing agent, the soluble thermoplastic polyimide contains the carboxyl group, and the functional groups of the curing agent are selected from the group consisting of: amino group, alcohol group, and isocyanate group.

Preferably, the curing agent contains at least two and at most four functional groups.

More preferably, a molar ratio of the functional groups of the curing agent relative to the carboxyl group of the soluble thermoplastic polyimide is 0.5:1 to 1:1.

More preferably, the curing agent is selected from the group consisting of: 9,9′-bis(4-aminophenyl)fluorine, N,N,N′,N′-tetrakis(4-aminophenyl)-1,4-benzenediamine, 1,3-bis(3-aminophenoxyl)benzene, 1,3-phenylene-di-4-aminophenylether, 1,3-bis[2-(4-aminophenyl)-2-propyl]benzene, 4,4′-diaminodiphenyl ether, diaminopyrimidine, triaminopyrimidine, ethylene glycol, hexalene glycol, hexamethylene diisocyanate, 1,5-naphthalene diisocyanate, and combinations thereof.

Preferably, the polar aprotic solvent is selected from the group consisting of: tetrahydrofuran, N,N-dimethylformide, N,N-dimethylacetamide, N-methyl-2-pyrrolidone, γ-butyrolactone, dimethyl sulfoxide and combinations thereof.

Preferably, the first diamine is selected from the group consisting of: 3,4′-diaminodiphenyl ether, 4,4′-diaminodiphenyl ether, p-phenylenediamine, m-phenylenediamine, 2,2′-bis(4-aminophenyl)propane, 4,4′-diaminodiphenyl methane, 4,4′-diaminodiphenyl sulfone, 3,3′-diaminodiphenyl sulfone, 4,4′-diaminodiphenyl sulfide, 1,3-bis(4-aminophenoxy)benzene, 1,3-bis(3-aminophenoxy)benzene, 1,4-bis(4-aminophenoxy)benzene, 4,4-bis(4-aminophenoxy)biphenyl, 2,2′-bis[4-(4-aminophenoxy)phenyl]propane, 2,2′-bis[4-(3-aminophenoxy)phenyl]propane, 2,2′-dimethyl-4,4′-diaminobiphenyl, 3,3′-dimethyl-4,4′-diaminobiphenyl, 3,3′-dihydroxy-4,4′-diaminobiphenyl, 9,9′-bis(4-aminophenyl)fluorine, 2,2-bis[4-(3-aminophenoxy)benzene]sulfone, 2,6-diaminopyrimidine, polyoxypropylenediamine, 4,4′-(1,3-phenylenediisopropylidene)bisaniline, 4,4′-(1,4-phenylenediisopropylidene)bisaniline, norbornane dimethylamine, and combinations thereof.

Preferably, the second diamine is selected from the group consisting of: 6,6′-diamino-3,3′-methanediyldibenzoic acid, 3,5-diaminobenzoic acid, and a combination thereof.

Preferably, the dianhydride is selected from the group consisting of: pyromellitic dianhydride, 3,3′,4,4′-biphenyl tetracarboxylic dianhydride, 3,3′,4,4′-benzophenone tetracarboxylic dianhydride, 4,4′-oxydiphthalic dianhydride, 3,3′,4,4′-diphenylsulfone tetracarboxylic dianhydride, 2,2′-bis(4-carboxyphenyl)hexafluoropropane, ethylene glycol-bis(trimellitate anhydride), 1,3-dihydro-1,3-dioxo-5-isobenzofurancarboxylic acid phenylene ester, 1,2,3,4-butanetetracarboxylic dianhydride, 1,2,3,4-cyclopentanetetracarboxylic dianhydride ,and combinations thereof

Preferably, the content of the dianhydride ranges from 90 mol. % to 99 mol. % based on the total content of the first diamine and the second diamine.

Preferably, a viscosity of the composition ranges from 150 centipoises (cps) to 15,000 cps under 25° C. and 101325 Pascal (Pa).

Preferably, an acid value of the composition ranges from 5 mgKOH/g to 150 mgKOH/g.

The composition in accordance with the present invention is made from the method mentioned above.

The present invention also provides a polyimide metal laminate and a method of making the laminate.

The polyimide metal laminate in accordance with the present invention has:

a polyimide film having two opposite sides;

at least one connecting layer made from the composition mentioned above, each of the at least one connecting layer is laminated on one of the sides of the polyimide film; and

at least one metal foil laminated on the at least one connecting layer.

Preferably, each connecting layer has a thermal expansion rate equal to or less than 11% under 250° C. to 350° C. More preferably, each connecting layer has a thermal expansion rate equal to or less than 9% under 250° C. to 350° C.

Preferably, a peeling strength between each connecting layer and the metal foil laminated on each connecting layer is larger than 0.8 kgf/cm.

Preferably, each of the at least one connecting layer is 1 μm to 6 μm in thickness.

The method of making the laminate in accordance with the present invention comprises the steps of:

coating the composition mentioned above on at least one of two opposite sides of a polyimide film to form at least one coating layer on the polyimide film;

drying the at least one coating layer to obtain at least one connecting layer laminated on the polyimide film; and

hot-pressing at least one metal foil on the at least one connecting layer to obtain the laminate.

Preferably, the step of drying the at least one coating layer to obtain at least one connecting layer laminated on the polyimide film comprises the steps of:

drying the at least one coating layer under 140° C. to 180° C. for 5 minutes to 15 minutes to obtain at least one dried coating layer; and

drying the at least one dried coating layer under 200° C. to 300° C. for 5 minutes to 15 minutes to obtain the at least one connecting layer laminated on the polyimide film.

Preferably, the step of hot-pressing the at least one metal foil on the at least one connecting layer to obtain the laminate comprises the steps of:

covering the at least one metal foil on the at least one connecting layer to obtain a semi-product;

pre-heating the semi-product under 350° C. to 400° C. for 3 minutes to 10 minutes; and

pressing the at least one metal foil on the at least one connecting layer under a pressure ranging from 300 kg/cm² to 400 kg/cm² for 5 minutes to 10 minutes to obtain the laminate.

In accordance with the method of making the composition of the present invention, most preferably, the species of the functional groups of the curing agent is amino group. Accordingly, the heat resistance of the connecting layer made from the composition is enhanced.

By controlling the content of the dianhydride within a range from 85 mol. % to 99 mol. % based on the total content of the first diamine and the second diamine, the soluble thermoplastic polyimide composition made from foresaid method can be laminated with a commercial polyimide film and a metal foil via simple steps of coating, drying, and pressing, to form a polyimide metal laminate. Accordingly, the step of imidizing the polyamide acid on a copper foil in the conventional method is omitted. Therefore, by utilizing the soluble thermoplastic polyimide composition, the method of making the polyimide metal laminate of the present invention is simpler and more economical than the conventional method.

Other objectives, advantages and novel features of the invention will become more apparent from the following detailed description.

### DETAILED DESCRIPTION OF THE PREFERRED EMBODIMENTS

### Preparation Example 1

### Making of Soluble Thermoplastic Polyimide Composition

Firstly, 0.45 grams of p-phenylenediamine, 2.41 grams of 4,4′-(1,3-phenylenediisopropylidene)bisaniline, 3.67 grams of 1,3-bis(3-aminophenoxy)benzene, and 0.64 grams of 3,5-diaminobenzoic acid were dissolved in 105 grams of N-methyl-2-pyrrolidone and a first solution was obtained. 4.50 grams of 3,3′,4,4′-benzophenone tetracarboxylic dianhydride and 3.70 grams of 3,3′,4,4′-biphenyl tetracarboxylic dianhydride were added into the first solution and a second solution was obtained. The second solution was processed with polymerization under 25° C. for 12 hours and a polyamide acid was obtained.

Secondly, 30 grams of toluene was mixed with the polyamide acid and a pre-reaction solution was obtained. The pre-reaction solution was held under 190° C. for 1 hour for imidization to obtain a polyimide solution. The polyimide solution was heated to 150° C. and vacuumed to isolate toluene and water from the polyimide solution, so as to obtain the soluble thermoplastic polyimide composition having a carboxyl group. Toluene served as an azeotropic agent and water was a by-product of imidization.

In the present preparation example, the soluble thermoplastic polyimide composition was consisted of soluble thermoplastic polyimide. The total content of 3,3′,4,4′-benzophenone tetracarboxylic dianhydride and 3,3′,4,4′-biphenyl tetracarboxylic dianhydride was 95 mol. % based on the total content of p-phenylenediamine, 4,4′-(1,3-phenylenediisopropylidene)bisaniline, 1,3-bis(4-aminophenoxy)benzene, and 3,5-diaminobenzoic acid. The viscosity of the soluble thermoplastic polyimide composition under 25° C. and 101325 Pa was 270 cps. The acid value of the soluble thermoplastic polyimide composition was 15 mgKOH/g.

In the present preparation example, the soluble thermoplastic polyimide composition was marked as STPI-A.

### Preparation Example 2

### Making of Soluble Thermoplastic Polyimide Composition

The method of the present preparation example was performed similarly to Preparation example 1. The differences of the methods between the present preparation example and Preparation example 1 were as follows.

In the present preparation example, 15 grams of the soluble thermoplastic polyimide was mixed with 0.043 grams of a curing agent containing multiple functional groups to obtain the soluble thermoplastic polyimide composition. The curing agent was 4,4′-diaminodiphenyl ether, which contained two amino groups. The molar ratio of the functional groups of the curing agent relative to the carboxyl group of the soluble thermoplastic polyimide was 0.9:1.

In the present preparation example, the viscosity of the soluble thermoplastic polyimide composition under 25° C. and 101325 Pa was 270 cps, the acid value of the soluble thermoplastic polyimide composition was 15 mgKOH/g, and the soluble thermoplastic polyimide composition was marked as STPI-A1.

### Preparation Example 3

### Making of Soluble Thermoplastic Polyimide Composition

The method of the present preparation example was performed similarly to Preparation example 2. The differences of the methods between the present preparation example and Preparation example 2 were as follows.

In the present preparation example, 15 grams of the soluble thermoplastic polyimide was mixed with 0.018 grams of the curing agent containing multiple functional groups to obtain the soluble thermoplastic polyimide composition. The curing agent containing multiple functional groups was triaminopyrimidine, which contained three amino groups. The molar ratio of the functional groups of the curing agent relative to the carboxyl group of the soluble thermoplastic polyimide was 0.9:1.

In the present preparation example, the viscosity of the soluble thermoplastic polyimide composition under 25° C. and 101325 Pa was 265 cps, the acid value of the soluble thermoplastic polyimide composition was 15 mgKOH/g, and the soluble thermoplastic polyimide composition was marked as STPI-A2.

### Preparation Example 4

### Making of Soluble Thermoplastic Polyimide Composition

The method of the present preparation example was performed similarly to Preparation example 2. The differences of the methods between the present preparation example and Preparation example 2 were as follows.

In the present preparation example, 15 grams of the soluble thermoplastic polyimide was mixed with 0.051 grams of the curing agent containing multiple functional groups to obtain the soluble thermoplastic polyimide composition. The curing agent containing multiple functional groups was N,N,N′,N′-Tetrakis(4-aminophenyl)-1,4-benzenediamine, which contained four amino groups. The molar ratio of the functional groups of the curing agent relative to the carboxyl group of the soluble thermoplastic polyimide was 0.9:1.

In the present preparation example, the viscosity of the soluble thermoplastic polyimide composition under 25° C. and 101325 Pa was 260 cps, the acid value of the soluble thermoplastic polyimide composition was 15 mgKOH/g, and the soluble thermoplastic polyimide composition was marked as STPI-A3.

### Preparation Example 5

### Making of Soluble Thermoplastic Polyimide Composition

The method of the present preparation example was performed similarly to Preparation example 1. The differences of the methods between the present preparation example and Preparation example 1 were as follows.

In the present preparation example, 0.40 grams of p-phenylenediamine, 2.25 grams of 4,4′-(1,3-phenylenediisopropylidene)bisaniline, 1.63 grams of 1,3-bis(3-aminophenoxy)benzene, and 0.43 grams of 3,5-diaminobenzoic acid were dissolved in 90 grams of N-methyl-2-pyrrolidone to obtain the first solution. 3.60 grams of 3,3′,4,4′-benzophenone tetracarboxylic dianhydride and 1.92 grams of 3,3′,4,4′-biphenyl tetracarboxylic dianhydride were added into the first solution separetely to obtain the second solution. The second solution was processed with polymerization under 25° C. for 12 hours to obtain the polyamide acid.

In the present preparation example, the total content of 3,3′,4,4′-benzophenone tetracarboxylic dianhydride and 3,3′,4,4′-biphenyl tetracarboxylic dianhydride was 99 mol. % based on the total content of p-phenylenediamine, 4,4′-(1,3-phenylenediisopropylidene)bisaniline, 1,3-bis(4-aminophenoxy)benzene, and 3,5-diaminobenzoic acid. The viscosity of the soluble thermoplastic polyimide composition under 25° C. and 101325 Pa was 520 cps, the acid value of the soluble thermoplastic polyimide composition was 15 mgKOH/g, and the soluble thermoplastic polyimide composition was marked as STPI-B.

### Preparation Example 6

### Making of Soluble Thermoplastic Polyimide Composition

The method of the present preparation example was performed similarly to Preparation example 5. The differences of the methods between the present preparation example and Preparation example 5 were as follows.

In the present Preparation example, 15 grams of the soluble thermoplastic polyimide was mixed with 0.018 grams of a curing agent containing multiple functional groups to obtain the soluble thermoplastic polyimide composition. The curing agent containing multiple functional groups was triaminopyrimidine, which contained three amino groups. The molar ratio of the functional groups of the curing agent relative to the carboxyl group of the soluble thermoplastic polyimide was 0.9:1.

In the present preparation example, the viscosity of the soluble thermoplastic polyimide composition under 25° C. and 101325 Pa was 520 cps, the acid value of the soluble thermoplastic polyimide composition was 15 mgKOH/g, and the soluble thermoplastic polyimide composition was marked as STPI-B1.

### Preparation Example 7

### Making of Soluble Thermoplastic Polyimide Composition

The method of the present preparation example was performed similarly to Preparation example 1. The differences of the methods between the present preparation example and Preparation example 1 were as follows.

In the present preparation example, 5.33 grams of 2,2′-bis[4-(4-aminophenoxy)phenyl]propane,4.87 grams of 1,3-bis(3-aminophenoxy)benzene, and 0.51 grams of 3,5-diaminobenzoic acid were dissolved in 80 grams of N-methyl-2-pyrrolidone to obtain the first solution. 1.82 grams of pyromellitic dianhydride, 1.55 grams of 4,4′-oxydiphthalic dianhydride, 0.54 grams of 3,3′,4,4′-benzophenone tetracarboxylic dianhydride, and 5.39 grams of 3,3′,4,4′-biphenyl tetracarboxylic dianhydride were added into the first solution separately to obtain the second solution. The second solution was processed with polymerization under 25° C. for 12 hours to obtain the polyamide acid.

In the present preparation example, the total content of pyromellitic dianhydride, 4,4′-oxydiphthalic dianhydride, 3,3′,4,4′-benzophenone tetracarboxylic dianhydride, and 3,3′,4,4′-biphenyl tetracarboxylic dianhydride was 95 mol. % based on the total content of 2,2′-bis[4-(4-aminophenoxy)phenyl]propane, 1,3-bis(3-aminophenoxy)benzene, and 3,5-diaminobenzoic acid. The viscosity of the soluble thermoplastic polyimide composition under 25° C. and 101325 Pa was 305 cps, the acid value of the soluble thermoplastic polyimide composition was 10 mgKOH/g, and the soluble thermoplastic polyimide composition was marked as STPI-C.

### Preparation Example 8

### Making of Soluble Thermoplastic Polyimide Composition

The method of the present preparation example was performed similarly to Preparation example 7. The differences of the methods between the present preparation example and Preparation example 7 were as follows.

In the present preparation example, 15 grams of the soluble thermoplastic polyimide was mixed with 0.012 grams of a curing agent containing multiple functional groups to obtain the soluble thermoplastic polyimide composition. The curing agent containing multiple functional groups was triaminopyrimidine, which contained three amino groups. The molar ratio of the functional groups of the curing agent relative to the carboxyl group of the soluble thermoplastic polyimide was 0.9:1.

In the present preparation example, the viscosity of the soluble thermoplastic polyimide composition under 25° C. and 101325 Pa was 300 cps, the acid value of the soluble thermoplastic polyimide composition was 15 mgKOH/g, and the soluble thermoplastic polyimide composition was marked as STPI-C1.

### Preparation Example 9

### Making of Polyimide Metal Laminate

The soluble thermoplastic polyimide composition of Preparation example 1 was coated on a side of a commercial polyimide film to form a coating layer on the polyimide film. The coating layer was first dried under 160° C. for 10 minutes in an oven to obtain a dried coating layer on the polyimide film. The dried coating layer was then dried under 250° C. for 10 minutes in the oven for fully drying, and a connecting layer on the polyimide film was obtained. And then, a copper foil was covered on the connecting layer and a semi-product was obtained. After the semi-product was pre-heated under 380° C. for 5 minutes, the copper foil and the connecting layer were pressed under a pressure of 350 kg/cm² for 10 minutes and the polyimide metal laminate of the present preparation example was obtained.

In the present preparation example, the commercial polyimide film was EZ 200 of DuPont Company, U.S.A. The commercial polyimide film was 50 μm in thickness. The connecting layer was 2 μm to 3 μm in thickness. The copper foil was ⅓ oz electrolytic copper foil purchased from Chang Chun Group, Taiwan.

### Preparation Examples 10 to 16

### Making of Polyimide Metal Laminate

The steps of making a polyimide metal laminate of Preparation examples 10 to 16 were similar to those of Preparation example 9. The differences between Preparation examples 10 to 16 and Preparation example 9 were that the soluble thermoplastic polyimide compositions of Preparation examples 2 to 8 were respectively applied to make the polyimide metal laminates of Preparation examples 10 to 16.

### Preparation Example 17

### Making of Polyimide Metal Laminate

The soluble thermoplastic polyimide composition of Preparation example 1 was coated on two opposite sides of a commercial polyimide film to form two coating layers on the two sides of the polyimide film respectively. The coating layers were first dried under 160° C. for 10 minutes in an oven to obtain two dried coating layers on the two sides of the polyimide film. The dried coating layers were dried under 250° C. for 10 minutes in the oven for fully drying and two connecting layers on the two sides of the polyimide film were obtained. And then, two copper foils were respectively covered on the connecting layers and a semi-product was obtained. After the semi-product was pre-heated under 380° C. for 5 minutes, the copper foils and the corresponding connecting layer were pressed under a pressure of 350 kg/cm² for 10 minutes and the polyimide metal laminate of the present preparation example was obtained.

### Test Example 1

### Peeling Strength and Solder Resistance

The peeling strength between the connecting layer and the copper foil of the polyimide metal laminates in Preparation examples 9 to 16 and the solder resistance of the same were measured in the present test.

The peeling strength was measured in accordance with IPC-TM-650 2.4.9.

The solder resistance was measured in accordance with IPC-TM-650 2.4.13. Based on IPC-TM-650 2.4.13, the polyimide metal laminates were preheated and soldered afloat at 300° C. for 10 seconds (hereinafter “300° C. /10 s”). If no blistering, delaminating, wrinkling, or popcorning was observed during the test, it was determined that the polyimide metal laminate passed the solder resistance evaluations and had good solder resistance.

### Test Example 2

### Thermal Expansion Rate, Decomposition Temperature, Glass Transition Temperature

The thermal expansion rate, decomposition temperature, glass transition temperature of each of the testing films made from each of the soluble thermoplastic polyimide compositions of Preparation examples 1 to 8 were measured in the present test example.

The steps to make each of the testing films were as follows:

Each of the soluble thermoplastic polyimide compositions of Preparation examples 1 to 8 was coated on a side of a copper foil and a coating layer was formed on the copper foil. The coating layer was first dried under 160° C. for 10 minutes in an oven to obtain a dried coating layer on the copper foil. The dried coating layer was dried under 250° C. for 10 minutes in the oven for fully drying and the testing film on the copper foil was obtained.

Specifically, the drying condition in the present test was the same as the drying condition of making the polyimide metal laminates in Preparation examples 9 to 16. Afterwards, the copper foil was etched away by copper dichloride (CuCl₂) in an etching machine and the testing film, which was on the copper foil, was left behind The testing film was 13 μm to 15 μm in thickness.

The testing film was heated from room temperature to a designated temperature with a gradient of 10° C. per minute and measured by Pyris Diamond thermal mechanical analyzer of PerkinElmer Co. to determine its thermal expansion rate. The thermal linear expansion rate was defined as (L₁-L₁)/L₁, wherein L₁ was designated to be the length of a testing film at the designated temperature, L₁ was designated to be the length of the testing film at room temperature. In the present test, the designated temperature was 300° C.

The thermal decomposition temperature was the temperature at which the weight of a testing film was 5.0% less than its weight measured at 300° C. The thermal decomposition temperature was measured by Pyris Diamond thermogravimetric/differential thermal analyzer of PerkinElmer Co. with a temperature gradient of 10° C. per minute.

The glass transition temperature was measured by Pyris Diamond thermal mechanical analyzer of PerkinElmer Co. with a temperature gradient of 10° C. per minute.

The results of Test example 1 and Test example 2 were shown in Tables 1 and 2. Note that the testing films in Test example 2 were made from the soluble thermoplastic polyimide compositions of Preparation examples 1 to 8, the connecting layers of the polyimide metal laminates of Preparation examples 9 to 16 were made from the soluble thermoplastic polyimide compositions of Preparation examples 1 to 8, and the drying condition for making the testing films in Test example 2 was same as the drying condition of making the polyimide metal laminates in Preparation examples 9 to 16. Hence, as a person skilled in the art of the present invention would understand, the thermal expansion rate, the decomposition temperature, and the glass transition temperature of the testing films made from the soluble thermoplastic polyimide compositions of Preparation examples 1 to 8 in Test example 2 were respectively regarded as the thermal expansion rate, the decomposition temperature, and the glass transition temperature of the connecting layers of the polyimide metal laminates of Preparation examples 9 to 16. Accordingly, in Tables 1 and 2, the thermal expansion rate, the decomposition temperature, and the glass transition temperature of the testing films in Test example 2 were respectively represented as the thermal expansion rate, the decomposition temperature, and the glass transition temperature of the connecting layers of the polyimide metal laminates of Preparation examples 9 to 16.

TABLE 1
The results of Test examples 1 and 2 (I)

| | | T_{g} of | T_{d} of | |
|---|---|---|---|---|
| | Raw material | connecting | connecting | Peeling |
| Preparation | for connecting | layer of | layer of | strength of |
| example | layer of | laminate | laminate | laminate |
| No. | laminate plate | plate | plate | plate |
| 9 | STPI-A | 259° C. | 524° C. | 1.02 kgf/cm |
| 10 | STPI-A1 | 261° C. | 520° C. | 0.98 kgf/cm |
| 11 | STPI-A2 | 262° C. | 526° C. | 0.99 kgf/cm |
| 12 | STPI-A3 | 270° C. | 520° C. | 0.86 kgf/cm |
| 13 | STPI-B | 265° C. | 517° C. | 1.01 kgf/cm |
| 14 | STPI-B1 | 266° C. | 514° C. | 0.99 kgf/cm |
| 15 | STPI-C | 262° C. | 511° C. | 1.07 kgf/cm |
| 16 | STPI-C1 | 265° C. | 515° C. | 1.03 kgf/cm |

With reference to Table 1, as seen from the connecting layers of the polyimide metal laminates of Preparation examples 9 to 12, the glass transition temperature of a connecting layer was affected by the curing agents containing different amounts of functional groups. However, if the curing agents used contained a proper amount of functional groups, the glass transition temperature of a connecting layer of a polyimide metal laminate would be held while good peeling strength between the connecting layer and copper foil would be sustained. For instance, STPI-A had no curing agent, STPI-A1 had a curing agent containing two functional groups (amino groups), and STPI-A2 had a curing agent containing three functional groups (amino groups), the glass transition temperature of the connecting layer of the polyimide metal laminates of Preparation examples 9 to 11 were almost equal while good peeling strength between the connecting layer and copper foil of the polyimide metal laminates of Preparation examples 9 to 11 was sustained. Also, if the curing agents used contained an improper amount of functional groups, the glass transition temperature of a connecting layer of a polyimide metal laminate would be raised and the peeling strength between the connecting layer and copper foil would be decreased. For instance, STPI-A3 had a curing agent containing four functional groups (amino groups). Compared with the polyimide metal laminates of Preparation examples 9 to 11, the glass transition temperature of the connecting layer of the polyimide metal laminate of Preparation example 12 was higher and the peeling strength between the connecting layer and copper foil of the same was lower. Hence, by means of selecting the curing agents containing specific amount of functional groups, the peeling strength between the connecting layer and copper foil could be adjusted.

With reference to Table 1, as seen from the facts that each of the curing agents of STPI-A1, STPI-A2, STPI-A3, STPI-B1, and STPI-C1 contained 2, 3, or 4 functional groups (amino groups) and the peeling strength between the connecting layer and the copper foil of each of the polyimide metal laminates of Preparation examples 10 to 12, 14, and 16 was larger than 0.8 kgf/cm, the peeling strength between a connecting layer and a copper foil of a polyimide metal laminate was larger than 0.8 kgf/cm by selecting a curing agent containing 2, 3,or 4 functional groups and the delamination between the connecting layer and the copper foil was prevented.

With reference to Table 1, as seen from the polyimide metal laminates of Preparation examples 9 to 16, the effect of the curing agents containing multiple functional groups on the decomposition temperature of the connecting layers was not obvious.

TABLE 2
The results of Test examples 1and 2 (II)

| | Raw material | Thermal expansion | Solder resistance |
|---|---|---|---|
| Preparation | for connecting | rate of connecting | of laminate plate |
| example | layer of | layer of laminate | under condition of |
| No. | laminate plate | plate at 300° C. | 300° C./30 s |
| 9 | STPI-A | 8.6% | Passed |
| 10 | STPI-A1 | 6.3% | Passed |
| 11 | STPI-A2 | 6.7% | Passed |
| 12 | STPI-A3 | 5.7% | Passed |
| 13 | STPI-B | 10.3% | Not passed |
| 14 | STPI-B1 | 8.2% | Passed |
| 15 | STPI-C | 10.9% | Not passed |
| 16 | STPI-C1 | 8.5% | Passed |

With reference to Table 2, the thermal expansion rate of the connecting layers of the polyimide metal laminates of Preparation examples 9 to 12, 14, and 16 were less than 9% at 300° C. and the polyimide metal laminates of Preparation examples 9 to 12, 14, and 16 passed the solder resistance test measured under the condition of 300° C. /10 s. In addition, the thermal expansion rate of the connecting layers of the polyimide metal laminates of Preparation examples 13 and 15 were larger than 9% at 300° C. and the polyimide metal laminates of Preparation examples 13 and 15 failed to pass the solder resistance test measured under the condition of 300° C. /10 s. Accordingly, a conclusion was made that when a connecting layer of a polyimide metal laminate as the polyimide metal laminates of Preparation examples 9 to 16 having a thermal expansion rate less than 9% at 300° C., the polyimide metal laminate was capable of passing the solder resistance test measured under the condition of 300° C. /10 s; that is, the polyimide metal laminate was not blistering, delaminating, wrinkling, or popcorning while soldering under the condition of 300° C. /10 s.

Further, after comparing Preparation examples 14 and 15 and Preparation examples 16 and 17, a conclusion was made that by the curing agents containing multiple functional groups, a connecting layer of a polyimide metal laminate was adjusted to be less than 9% at 300° C. and the polyimide metal laminate was capable of passing the solder resistance test measured under the condition of 300° C. /10 s, such that the polyimide metal laminate was not blistering, delaminating, wrinkling, or popcorning while soldering under the condition of 300° C. /10 s.

Based on the above results, by controlling the content of the dianhydride within a range from 85 mol. % to 99 mol. % based on the total content of the first diamine and the second diamine, the soluble thermoplastic polyimide compositions made in Preparation examples 1 to 8 were capable of being laminated with the commercial polyimide film and the metal foil via simple steps of coating, drying, and pressing, to form the polyimide metal laminate of Preparation examples 9 to 17. Accordingly, the step of imidizing the polyamide acid on a copper foil in the conventional method of making a polyimide metal laminate was omitted. Therefore, by utilizing the soluble thermoplastic polyimide composition of the present invention, the method of making the polyimide metal laminate of the present invention is simpler and more economical than the conventional method.

Even though numerous characteristics and advantages of the present invention have been set forth in the foregoing description, together with details of the features of the invention, the disclosure is illustrative only. Changes may be made in the details within the principles of the invention to the full extent indicated by the broad general meaning of the terms in which the appended claims are expressed.

What is claimed is:

1. A method of making a soluble thermoplastic polyimide composition, comprising the steps of:
polymerizing a first diamine, a second diamine different from the first diamine, and a dianhydride in a polar aprotic solvent to obtain a polyamine acid, wherein the first diamine contains a carboxyl group and a content of the dianhydride ranges from 85 mol. % to 99 mol. % based on the total content of the first diamine and the second diamine; and
imidizing the polyamine acid to obtain the composition, wherein the composition contains the carboxyl group.

2. The method of making the composition as claimed in claim 1, wherein the step of imidizing the polyamine acid to obtain the composition further comprises the steps of:
imidizing the polyamine acid to obtain a soluble thermoplastic polyimide; and
mixing the soluble thermoplastic polyimide and a curing agent containing at least two functional groups to obtain the composition, wherein the composition comprises the soluble thermoplastic polyimide and the curing agent, the soluble thermoplastic polyimide contains the carboxyl group, and the functional groups of the curing agent are selected from the group consisting of amino group, alcohol group, and isocyanate group.

3. The method of making the composition as claimed in claim 2, wherein the curing agent contains at least two and at most four functional groups.

4. The method of making the composition as claimed in claim 3, wherein the curing agent is selected from the group consisting of:
9,9′-bis(4-aminophenyl)fluorine, N,N,N′,N′-tetrakis(4-aminophenyl)-1,4-benzenediamine, 1,3-bis(3-aminophenoxyl)benzene, 1,3-phenylene-di-4-aminophenylether, 1,3-bis[2-(4-aminophenyl)-2-propyl]benzene, 4,4′-diaminodiphenyl ether, diaminopyrimidine, triaminopyrimidine, ethylene glycol, hexalene glycol, hexamethylene diisocyanate, 1,5-naphthalene diisocyanate, and combinations thereof.

5. The method of making the composition as claimed in claim 2, wherein a molar ratio of the functional groups of the curing agent relative to the carboxyl group of the soluble thermoplastic polyimide is 0.5:1 to 1:1.

6. The method of making the composition as claimed in claim 1, wherein the first diamine is selected from the group consisting of:
3,4′-diaminodiphenyl ether, 4,4′-diaminodiphenyl ether, p-phenylenediamine, m-phenylenediamine, 2,2′-bis(4-aminophenyl)propane, 4,4′-diaminodiphenyl methane, 4,4′-diaminodiphenyl sulfone, 3,3′-diaminodiphenyl sulfone, 4,4′-diaminodiphenyl sulfide, 1,3-bis(4-aminophenoxy)benzene, 1,3-bis(3-aminophenoxy)benzene, 1,4-bis(4-aminophenoxy)benzene, 4,4-bis(4-aminophenoxy)biphenyl, 2,2′-bis[4-(4-aminophenoxy)phenyl]propane, 2,2′-bis[4-(3-aminophenoxy)phenyl]propane, 2,2′-dimethyl-4,4′-diaminobiphenyl, 3,3′-dimethyl-4,4′-diaminobiphenyl, 3,3′-dihydroxy-4,4′-diaminobiphenyl, 9,9′-bis(4-aminophenyl)fluorine, 2,2-bis[4-(3-aminophenoxy)benzene]sulfone, 2,6-diaminopyrimidine, polyoxypropylenediamine, 4,4′-(1,3-phenylenediisopropylidene)bisaniline, 4,4′-(1,4-phenylenediisopropylidene)bisaniline, norbornane dimethylamine, and combinations thereof.

7. The method of making the composition as claimed in claim 1, wherein the second diamine is selected from the group consisting of:
6,6′-diamino-3,3′-methanediyldibenzoic acid, 3,5-diaminobenzoic acid, and a combination thereof.

8. The method of making the composition as claimed in claim 1, wherein the dianhydride is selected from the group consisting of: pyromellitic dianhydride, 3,3′,4,4′-biphenyl tetracarboxylic dianhydride, 3,3′,4,4′-benzophenone tetracarboxylic dianhydride, 4,4′-oxydiphthalic dianhydride, 3,3′,4,4′-diphenylsulfone tetracarboxylic dianhydride, 2,2′-bis(4-carboxyphenyl)hexafluoropropane, ethylene glycol-bis(trimellitate anhydride), 1,3-dihydro-1,3-dioxo-5-isobenzofurancarboxylic acid phenylene ester, 1,2,3,4-butanetetracarboxylic dianhydride, 1,2,3,4-cyclopentanetetracarboxylic dianhydride, and combinations thereof.

9. The method of making the composition as claimed in claim 1, wherein a viscosity of the composition ranges from 150 cps to 15,000 cps.

10. The method of making the composition as claimed in claim 1, wherein the content of the dianhydride ranges from 90 mol. % to 99 mol. % based on the total content of the first diamine and the second diamine.

11. The method of making the composition as claimed in claim 1, wherein an acid value of the composition ranges from 5 mgKOH/g to 150 mgKOH/g.

12. A soluble thermoplastic polyimide composition made from the method as claimed in claim 1.

13. A polyimide metal laminate having:
a polyimide film having two opposite sides;
at least one connecting layer made from the composition as claimed in claim 12, each of the at least one connecting layer is laminated on one of the sides of the polyimide film; and
at least one metal foil laminated on the at least one connecting layer.

14. The laminate as claimed in claim 13, wherein each connecting layer has a thermal expansion rate equal to or less than 11%.

15. The laminate as claimed in claim 14, wherein each connecting layer has a thermal expansion rate equal to or less than 9%.

16. The laminate as claimed in claim 13, wherein a peeling strength between each connecting layer and the metal foil laminated on each connecting layer is larger than 0.8 kgf/cm.

17. The laminate as claimed in claim 13, wherein each connecting layer is 1 μm to 6 μm in thickness.

18. A method of making a polyimide metal laminate, comprising the steps of:
coating the soluble thermoplastic polyimide composition as claimed in claim 12 on at least one of two opposite sides of a polyimide film to form at least one coating layer on the polyimide film;
drying the at least one coating layer to obtain at least one connecting layer laminated on the polyimide film; and
hot-pressing at least one metal foil on the at least one connecting layer to obtain the laminate.

19. The method of making the laminate as claimed in claim 18, wherein the step of drying the at least one coating layer to obtain at least one connecting layer laminated on the polyimide film comprises the steps of:
drying the at least one coating layer under 140° C. to 180° C. for 5 minutes to 15 minutes to obtain at least one dried coating layer; and
drying the at least one dried coating layer under 200° C. to 300° C. for 5 minutes to 15 minutes to obtain the at least one connecting layer laminated on the polyimide film.

20. The method of making the laminate as claimed in claim 18, wherein the step of hot-pressing the at least one metal foil on the at least one connecting layer to obtain the laminate comprises the steps of:
covering the at least one metal foil on the at least one connecting layer to obtain a semi-product;
pre-heating the semi-product under 350° C. to 400° C. for 3 minutes to 10 minutes; and
pressing the at least one metal foil on the at least one connecting layer under a pressure ranging from 300 kg/cm² to 400 kg/cm² to obtain the laminate.
